(19) United States
(12) Patent Application Publication
(10) Pub. No.: US 2025/0323052 A1
(43) Pub. Date: Oct. 16, 2025

(54) METHOD OF PROCESSING SUBSTRATE USING SLURRY AND METHOD OF MANUFACTURING SEMICONDUCTOR DEVICE INCLUDING THE SAME

(71) Applicant: Samsung Electronics Co., Ltd., Suwon-si (KR)

(72) Inventors: HYUNSOO KIM, Suwon-si (KR); Haesung LEE, Suwon-si (KR); Donggeon KWAK, Suwon-si (KR); Myungjin SEO, Suwon-si (KR); MinSeong LEE, Suwon-si (KR); HYUNGMOOK KIM, Suwon-si (KR); BYOUNGJUN CHO, Suwon-si (KR)

(21) Appl. No.: 18/924,443

(22) Filed: Oct. 23, 2024

(30) Foreign Application Priority Data
Apr. 16, 2024 (KR) 10-2024-0050981

(51) Int. Cl. H01L 21/3105; H10B 12/00

(52) U.S. Cl. CPC H01L 21/31053; H10B 12/01

(57) ABSTRACT

A method of processing a substrate may be provided. The method may include preparing a substrate in a substrate processing apparatus, rotating a polishing pad on the substrate, and supplying a slurry on the polishing pad, wherein the supplying of the slurry includes supplying the slurry during a first time interval at a flow rate characterized by a first function and supplying the slurry during a second time interval at a flow rate characterized by a second function, each of the first function and the second function is a function of time, and the first function is different from the second function.

### CROSS-REFERENCE TO RELATED APPLICATIONS

This U.S. non-provisional patent application claims priority under 35 U.S.C. § 119 to Korean Patent Application No. 10-2024-0050981, filed on Apr. 16, 2024, in the Korean Intellectual Property Office, the entire contents of which are hereby incorporated by reference.

### BACKGROUND OF THE INVENTION

The inventive concept relates to a method of processing a substrate using a slurry and a method of manufacturing a semiconductor device including the same, and more specifically, relates to a method of processing a substrate using a slurry efficiently and a method of manufacturing a semiconductor device including the same.

Various processes may be performed to fabricate a semiconductor device. For example, a substrate may undergo a photolithography process, an etching process, and a deposition process in fabricating a semiconductor device. It may be required that a surface of the substrate be planarized prior to each process. A polishing process may be executed on the substrate. The polishing process may be fulfilled in a variety of ways. For example, a chemical mechanical polishing (CMP) process may be used to planarize the substrate and other elements of the semiconductor device.

### SUMMARY

An object of the inventive concept is to provide a method of processing a substrate that efficiently uses a slurry, and a method of manufacturing a semiconductor device including the same.

An object of the inventive concept is to provide a method of processing a substrate that reduces the amount of the slurry used while maintaining a polishing rate, and a method of manufacturing a semiconductor device including the same.

Embodiments of the inventive concept are not limited to solving the problems mentioned above, and other embodiments may solve problems not mentioned in the disclosure, and the implementation of such embodiments may be clearly understood by those skilled in the art from the description below.

A method of processing a substrate according to some embodiments of the inventive concept may include preparing a substrate in a substrate processing apparatus, rotating a polishing pad on the substrate, and supplying a slurry on the polishing pad, wherein the supplying of the slurry includes supplying the slurry during a first time interval at a flow rate characterized by a first function and supplying the slurry during a second time interval at a flow rate characterized by a second function, each of the first function and the second function is a function of time, and the first function is different from the second function.

A method of manufacturing a semiconductor device according to some embodiments of the inventive concept may include forming patterns on a substrate, forming a layer covering the substrate and the patterns, and supplying a slurry onto the layer during a planarization process of the layer, wherein the supplying of the slurry includes supplying the slurry during a first time interval at a flow rate characterized by a first function, supplying the slurry during a second time interval at a flow rate characterized by a second function, and repeatedly performing at least one of supplying the slurry a flow rate characterized by the first function for a first duration and supplying the slurry at a flow rate characterized by the second function for a second duration, and the first function and the second function are different from each other.

A method of manufacturing a semiconductor device according to some embodiments of the inventive concept may include forming a device isolation layer that fills a trench in a substrate, forming device isolation patterns from the device isolation layer through a first planarization process, forming bit lines and landing pads electrically connected to source/drain patterns between the device isolation patterns, forming an upper conductive layer covering a lower electrode and a capacitor dielectric layer formed on the landing pads, and forming an upper electrode from the conductive layer as through a second planarization process, wherein at least one of the first planarization process and the second planarization process includes supplying a slurry on the substrate during a first time interval and a second time interval to planarize the device isolation layer and the conductive layer, and the slurry is supplied at different flow rates in each of the first time interval and the second time interval.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a perspective view illustrating a substrate processing apparatus according to embodiments of the inventive concept.

FIG. 2 is a side view illustrating a substrate processing apparatus according to embodiments of the inventive concept.

FIG. 3 is a plan view illustrating a substrate processing apparatus according to embodiments of the inventive concept.

FIG. 4 is a flowchart illustrating a method of processing a substrate according to embodiments of the inventive concept.

FIGS. 5, 6, and 7 are diagrams illustrating a method of processing a substrate according to embodiments of the inventive concept.

FIGS. 8A, 8B, 8C, and 8D are diagrams illustrating a method of supplying a slurry according to embodiments of the inventive concept.

FIG. 9 is a flowchart illustrating a method of supplying a slurry for a method of processing a substrate according to an embodiment of the inventive concept.

FIG. 10 is a diagram illustrating a method of supplying a slurry according to an embodiment of the inventive concept.

FIGS. 11A, 11B, and 11C are cross-sectional views illustrating a method of manufacturing a semiconductor device according to embodiments of the inventive concept.

FIGS. 12A, 12B, 12C, 12D, and 12E are cross-sectional views illustrating a method of manufacturing a semiconductor device according to embodiments of the inventive concept.

### DETAILED DESCRIPTION

Hereinafter, embodiments of the inventive concept will be described with reference to the attached drawings, in which various embodiments are shown. The same reference numerals may refer to the same elements throughout the specification. The inventive concept may, however, be embodied in many different forms and should not be construed as limited to the example embodiments set forth herein. It should also be emphasized that the disclosure provides details of alternative examples, but such listing of alternatives is not exhaustive. The language of the claims should be referenced in determining the requirements of the inventive concept.

The term “substrate” may denote a base substrate (e.g., an initial semiconductor substrate forming the base of the wafer in the final wafer product, such as a bulk semiconductor substrate (e.g., formed of crystalline silicon), a silicon on insulator (SOI) substrate, etc.), or a stack structure including such a base substrate and layers formed on the substrate.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

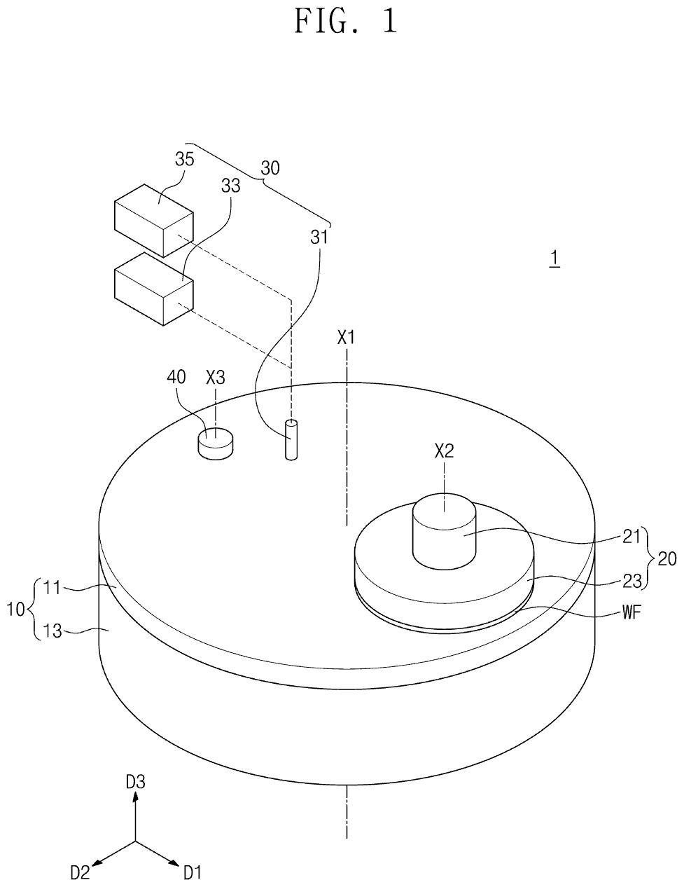

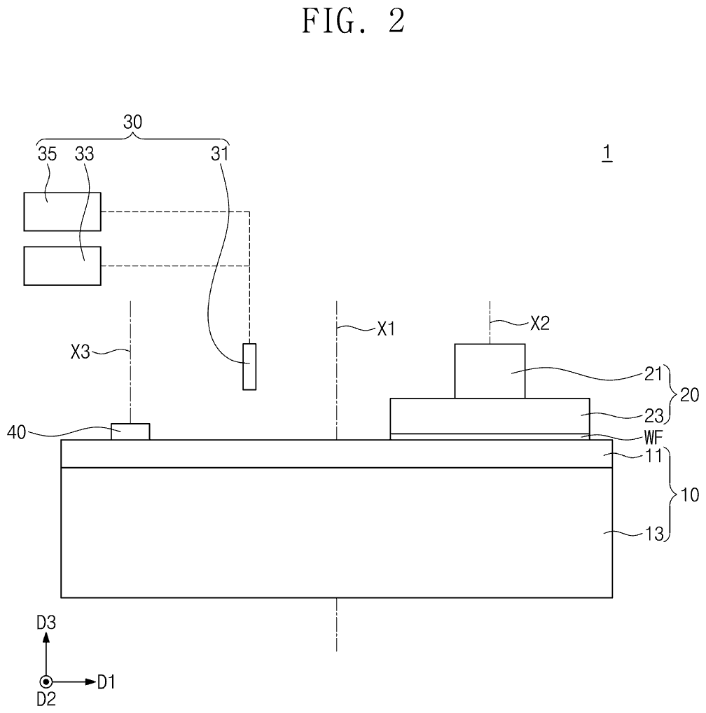

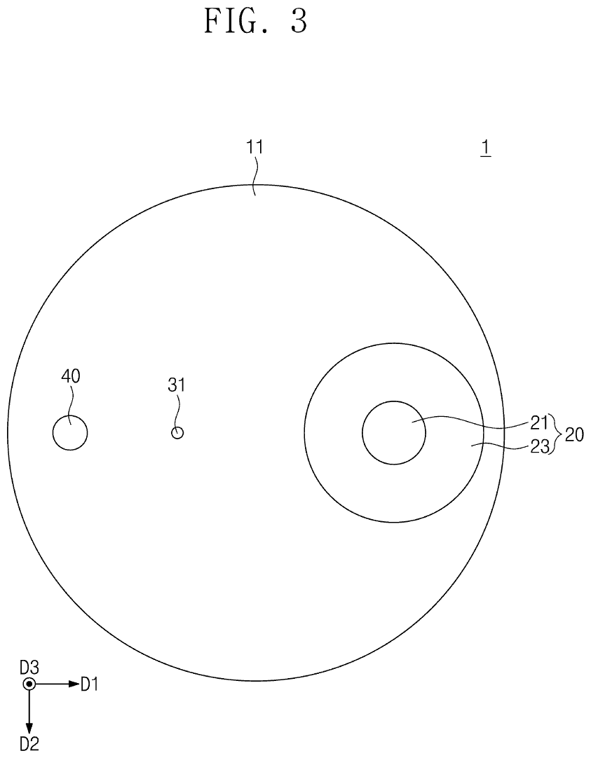

FIG. 1 is a perspective view illustrating a substrate processing apparatus according to embodiments of the inventive concept. FIG. 2 is a side view illustrating a substrate processing apparatus according to embodiments of the inventive concept. FIG. 3 is a plan view illustrating a substrate processing apparatus according to embodiments of the inventive concept.

Referring to FIGS. 1, 2, and 3, a substrate processing apparatus 1 may be provided as shown. For example, the substrate processing apparatus 1 may be a semiconductor apparatus that performs a chemical mechanical polishing (CMP) process. The substrate processing apparatus 1 may polish one side of the substrate WF (e.g., an upper side of the substrate WF). The term ‘substrate WF’ used in this specification may refer to a silicon (Si) wafer, but is not limited thereto. The substrate processing apparatus 1 may include a polisher 10, a polishing head 20, a slurry supply system 30, and a conditioning device 40.

The polisher 10 may include a polishing pad 11 and a plate 13. The polishing pad may be oriented such that an upper surface of the polishing pad is parallel to a first direction D1 (e.g., a first horizontal direction) and a second direction D2 (e.g., a second horizontal direction). The polisher 10 may have a first rotation axis X1 parallel to a third direction D3 (e.g., a vertical direction) and which may be perpendicular to the first direction D1 and the second direction D2. For example, the polisher 10 may rotate clockwise and/or counterclockwise about the first rotation axis X1.

The polishing pad 11 may be positioned on the plate 13. The polishing pad 11 may be coupled to the plate 13 while being in contact with an upper surface of the plate 13. The polishing pad 11 may polish the substrate WF. The polishing pad 11 may have a shape of a disk. For example, the polishing pad 11 may rotate about the first rotation axis X1 parallel to the third direction D3. An upper surface of the rotating polishing pad 11 may be in contact with the substrate WF and may polish a surface of the substrate WF. The polishing pad 11 may be divided into a plurality of areas, but is not limited thereto.

The plate 13 may be disposed below the polishing pad 11 and may support the polishing pad 11. The plate 13 may include a driving device and may rotate. For example, the driving device may include a rotary actuator, a motor, or a drive shaft. In some embodiments, the drive shaft may be rotated by a torque source external to the plate 13. For example, an external rotary actuator or motor may be coupled to the plate 13 through the drive shaft. Accordingly, the rotation of the plate 13 may rotate the polishing pad 11. When the polishing pad 11 has a shape of a disc, the plate 13 may also have a shape of a disc. For example, the plate 13 may rotate about the first rotation axis X1 parallel to the third direction D3. A rotation center of the plate 13 may be located on the same line as a rotation center of the polishing pad 11. That is, the polishing pad 11 may rotate as the plate 13 rotates, thereby polishing the substrate WF through relative motion between the polishing pad 11 and the substrate WF.

The polishing head 20 may be positioned on the polishing pad 11. The polishing head 20 may be horizontally spaced apart from the supply nozzle 31 of the slurry supply system 30 and the conditioning device 40, which will be described later. The polishing head 20 may include a head support 21 and a polishing head body 23.

The head support 21 may be positioned on the polishing head body 23. The head support 21 may be coupled to the polishing head body 23. The head support 21 may include a driving device such as a rotary actuator, a motor, or a drive shaft. In some embodiments, the drive shaft may be rotated by a torque source external to the head support 21. For example, an external rotary actuator or motor may be coupled to the head support 21 through the drive shaft. The head support 21 may have a second rotation axis X2 parallel to the third direction D3. The second rotation axis X2 may be horizontally spaced apart from the first rotation axis X1. The head support 21 may rotate clockwise and/or counterclockwise about the second rotation axis X2. Additionally, the head support 21 may move on the polishing pad 11 in a horizontal direction (e.g., in a first direction D1 and/or a second direction D2). The head support 21 may rise in the third direction D3 from a point where a lower surface of the polishing head body 23 is in contact with the polishing pad 11. For example, at least one linear actuator may be coupled to the head support 21 to cause it to move in one of the three directions. In some embodiments, a separate linear actuator may be provided for each direction of movement of the head support 21.

The polishing head body 23 may fix and support the substrate WF. The substrate may be fixed to the polishing head body 23 using vacuum pressure. For example, the polishing head body 23 may include a porous structure exposed on a lower surface thereof and a vacuum may be applied to the porous structure. The polishing head body 23 may rotate clockwise and/or counterclockwise due to the rotation of the head support 21. As a result, the polishing head 20 may support and/or rotate the substrate WF.

The slurry supply system 30 may be positioned on polishing pad 11. The slurry supply system 30 may include a supply nozzle 31, a slurry supply 33, and a controller 35. In some embodiments, the slurry supply 33 may be a chamber that may store slurry, or in other embodiments, the slurry supply may be a conduit in fluid communication with a source of slurry for delivery to the slurry supply system 30. The slurry from the slurry supply 33 may be discharged through the supply nozzle 31. The controller 35 may control the supply nozzle 31 to adjust the amount of the slurry discharged. The supply nozzle 31 may be spaced apart from the polishing pad 11 in the third direction D3. Additionally, the supply nozzle 31 may be disposed between the polishing head 20 and the conditioning device 40 in a direction parallel the surface of the plate 13 such as a rotational direction of the plate or a horizontal direction, which will be described later. The slurry discharged through the supply nozzle may enhance a chemical and mechanical polishing process for the substrate WF which may proceed smoothly due to the slurry discharged through the supply nozzle 31.

The conditioning device 40 may polish a portion of the polishing pad 11. The conditioning device 40 may be in selective contact with an upper surface of the polishing pad 11. For example, the conditioning device 40 may be in contact with the upper surface of the polishing pad 11 while the polishing pad 11 rotates. A condition of the upper surface of the polishing pad 11 may be changed by the conditioning device 40 during the chemical mechanical polishing process for the substrate WF. That is, the conditioning device 40 may improve the condition of the polishing pad 11 by polishing the polishing pad 11.

The conditioning device 40 may rotate independently of the polisher 10 and the polishing head 20. The conditioning device 40 may be rotated by a rotary actuator or a motor. Additionally, the position of the conditioning device may be changed by at least one linear actuator to move in at least one direction. The conditioning device 40 may have a shape of a disk. For example, the conditioning device 40 may have a third rotation axis X3 parallel to the third direction D3. The third rotation axis X3 may be horizontally spaced apart from the first and second rotation axes X1 and X2. A rotational speed of conditioning device 40 may be variously changed by time. The rotational speed of the conditioning device 40 may be changed under the control of the controller 35. A position of conditioning device 40 may be variously changed by time. The position of the conditioning device 40 may be changed under the control of the controller 35. For example, the conditioning device 40 may move on the polishing pad 11 in a horizontal direction (e.g., in a first direction D1 and a second direction D2). The conditioning device 40 may move up in the third direction D3 from a point where a lower surface of the conditioning device 40 is in contact with the polishing pad 11.

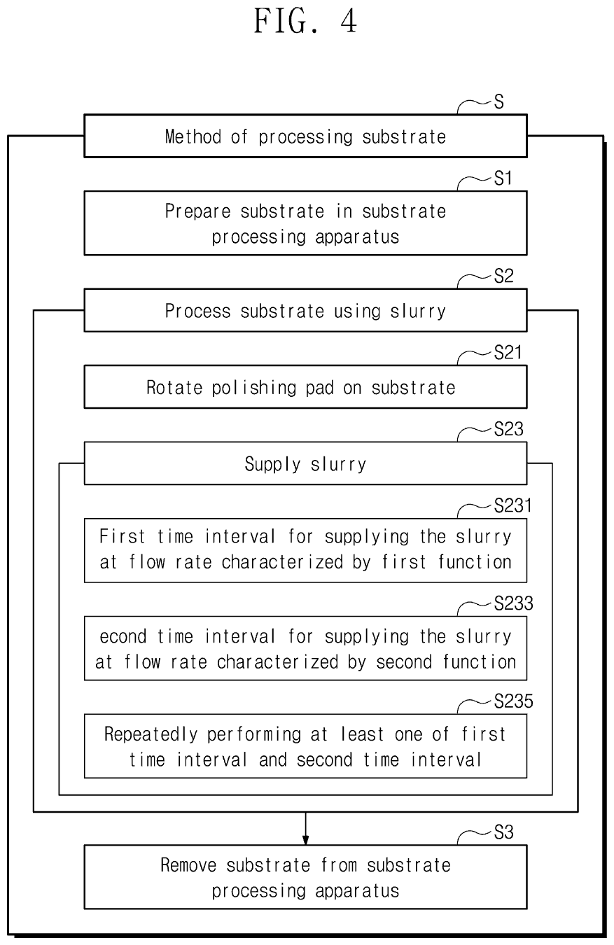

FIG. 4 is a flowchart illustrating method of processing a substrate according to embodiments of the inventive concept.

Referring to FIG. 4, a method of processing a substrate S is illustrated. For example, the method of processing the substrate S may be a method of chemical mechanical polishing a substrate using the substrate processing apparatus 1 described with reference to FIGS. 1 to 3. The method of processing the substrate S may include preparing a substrate in a substrate processing apparatus in S1, processing the substrate using a slurry in S2, and removing the substrate from the substrate processing apparatus in S3.

The processing of the substrate using the slurry in S2 may include rotating a polishing pad on the substrate in S21 and supplying the slurry to the polishing pad in S23. The supplying of the slurry in S23 may include performing a first supply activity that supplies the slurry at a flow rate characterized by a first function in S231, performing a second supply activity that supplies the slurry at a flow rate characterized by a second function in S233, and repeatedly performing at least one of the first supply activity and the second supply activity in S235.

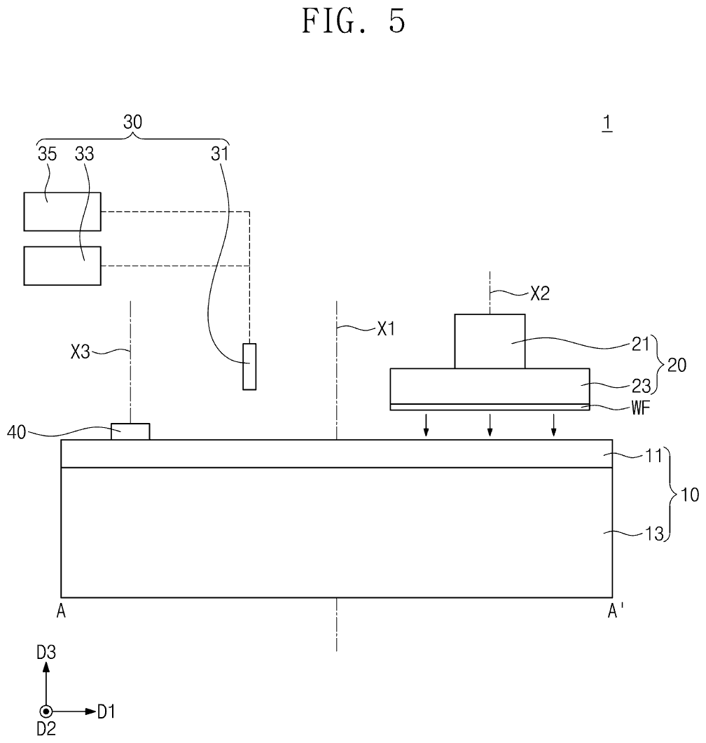

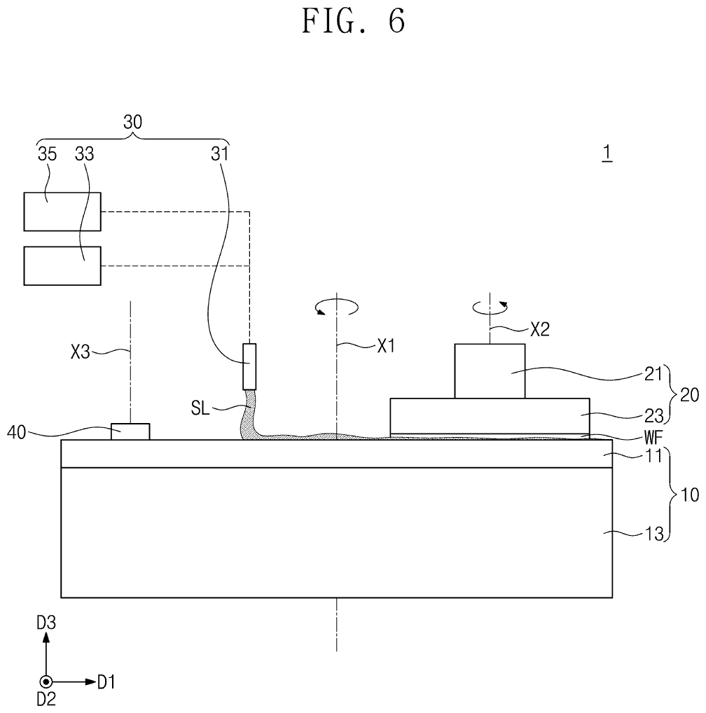

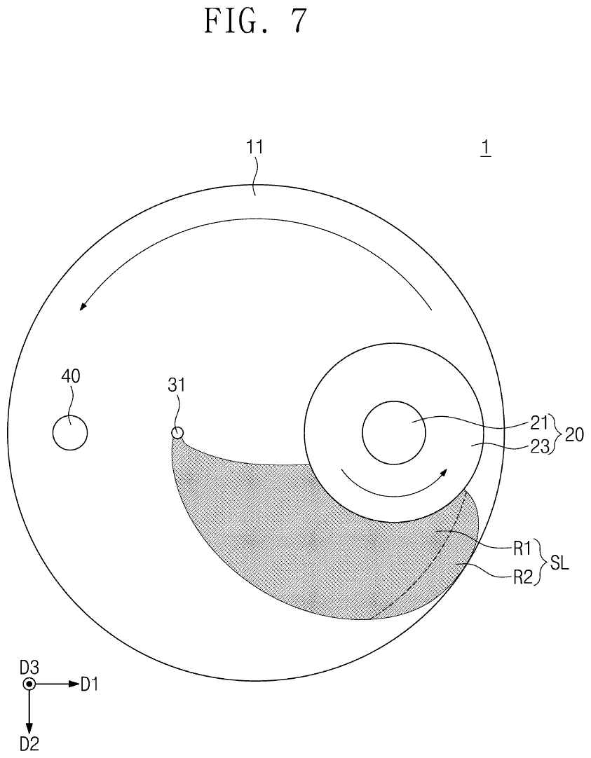

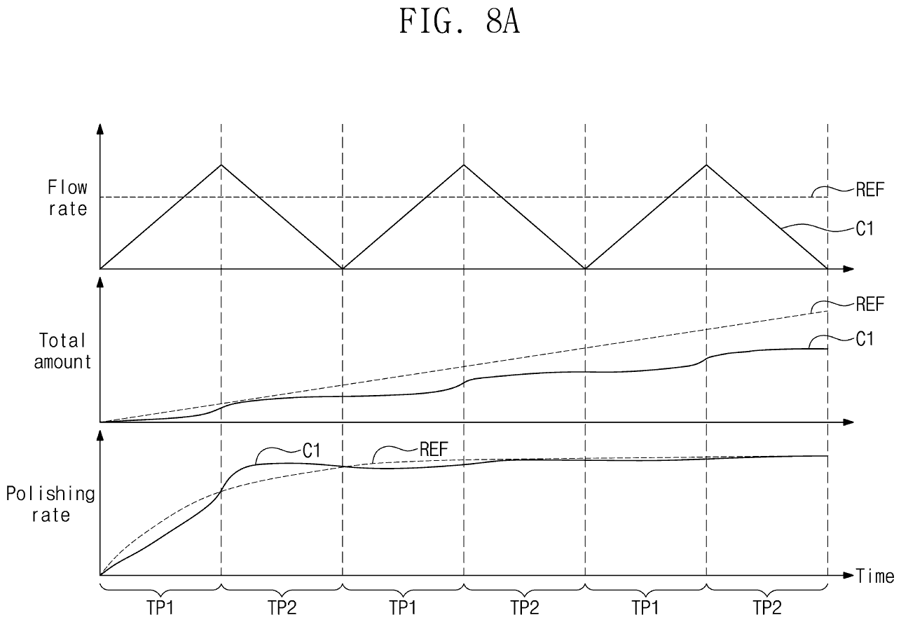

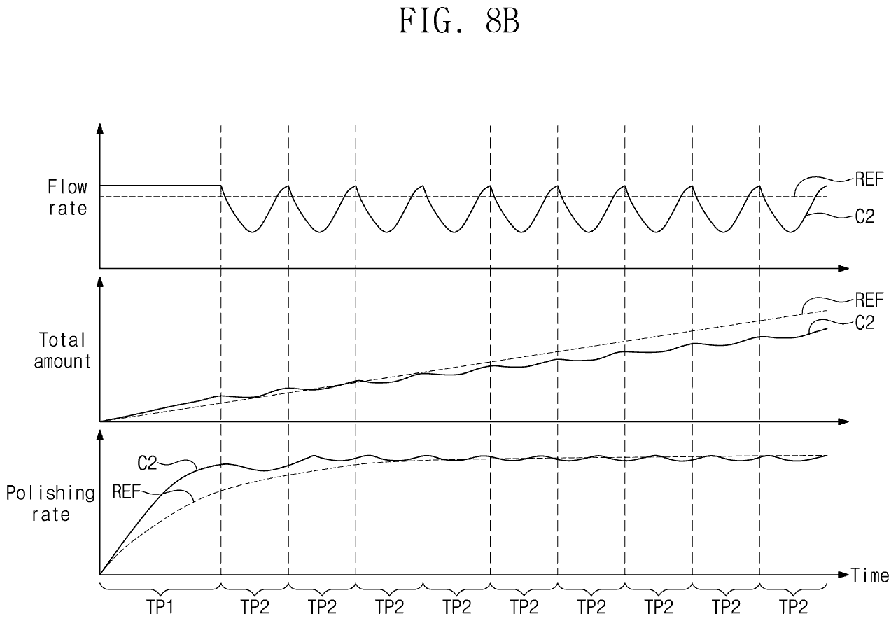

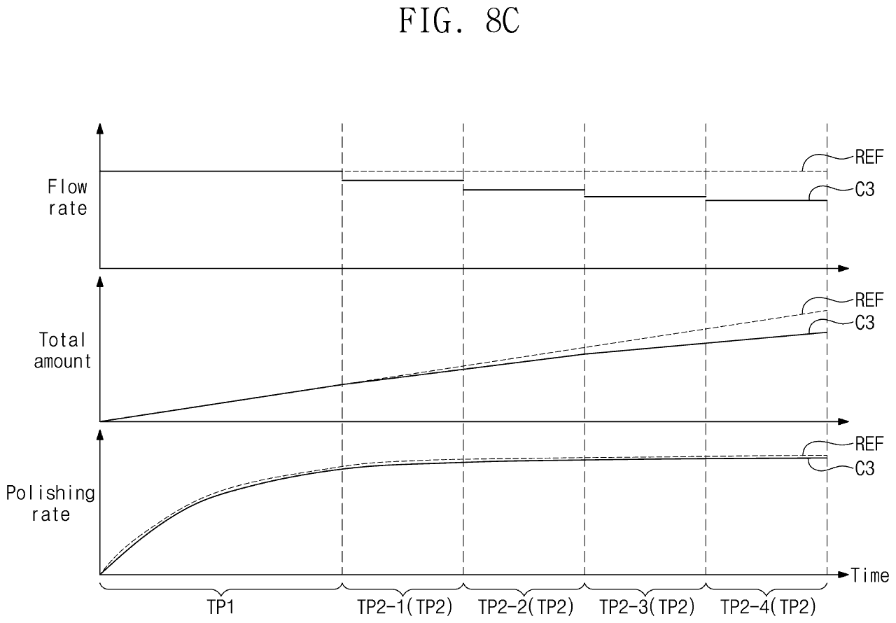

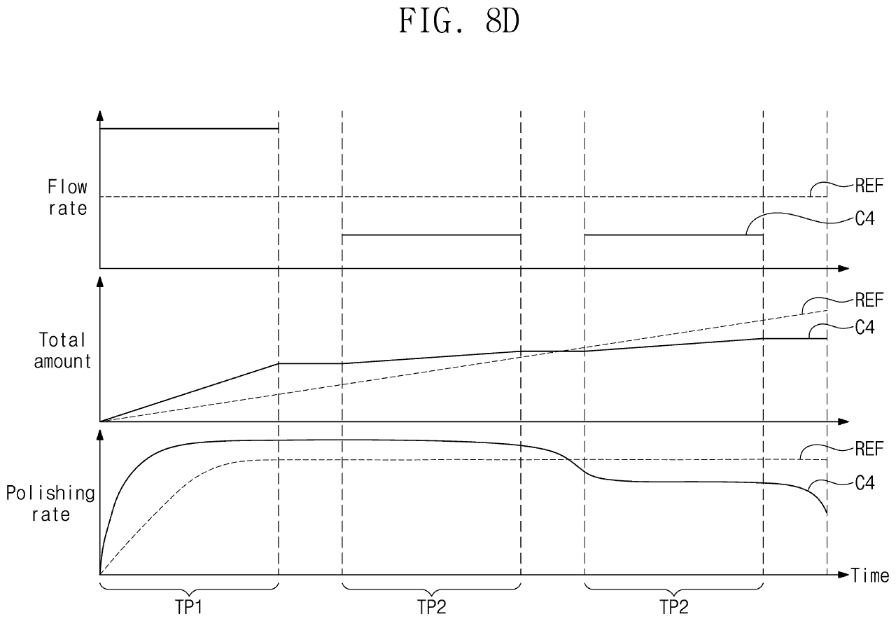

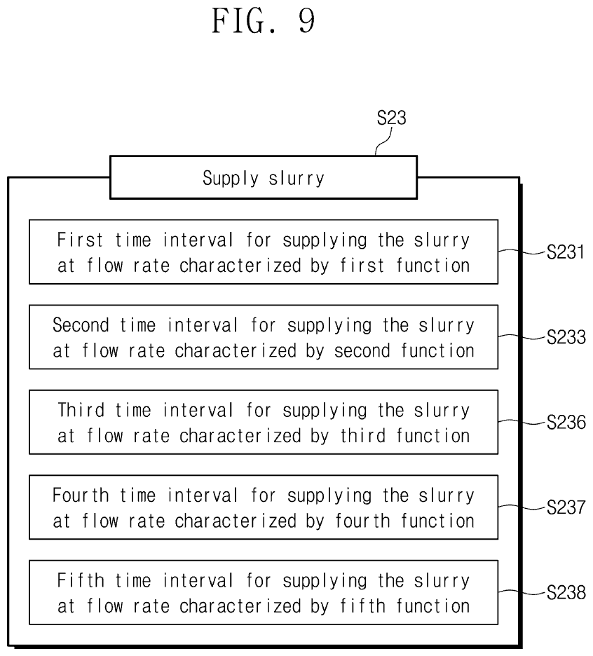

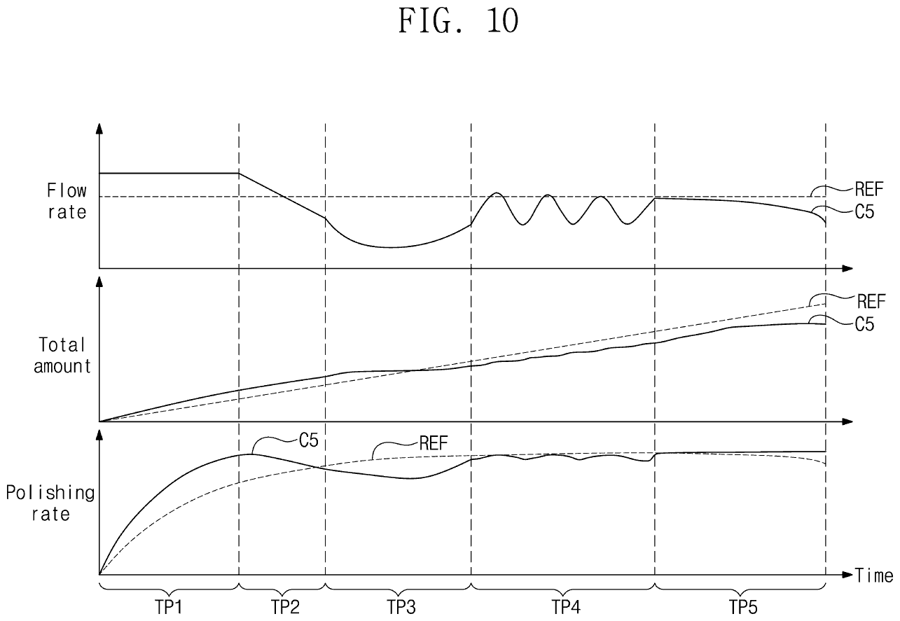

FIGS. 5 to 7 are diagrams illustrating examples of a substrate processing apparatus 1 during a method of processing a substrate according to embodiments of the inventive concept. FIGS. 8A to 8D are diagrams illustrating example flow rates of a slurry supplied during a method of supplying a slurry according to embodiments of the inventive concept. FIG. 9 is a flowchart illustrating a method of supplying a slurry for use in a method of processing a substrate according to an embodiment of the inventive concept. FIG. 10 is a diagram illustrating example flow rates of a slurry supplied during a method of supplying a slurry according to an embodiment of the inventive concept.

Referring to FIGS. 4 and 5, the preparing of the substrate in the substrate processing apparatus in S1 may include fixing the substrate WF to the polishing head body 23 of the polishing head 20 and lowering the head support 21 of the polishing head 20 to allow the substrate W to be adjacent and/or contact to the polishing pad.

As the polishing head body 23 may have a porous structure on a lower surface thereof, the polishing head body 23 may fix the substrate WF with vacuum pressure transmitted through the porous structure. For example, the substrate WF may be fixed to polishing head body 23 when the polishing head body is spaced apart from the polishing pad 11 in the third direction D3.

Thereafter, the head support 21 may descend in a direction opposite to the third direction D3 (e.g., downward). Accordingly, the polishing head 20 and the substrate WF may be adjacent to the polishing pad 11. For example, the substrate WF and the polishing pad 11 may be spaced apart enough for a portion of the slurry to flow therebetween. The substrate WF and the polishing pad 11 may be spaced apart no further than a distance at which a slurry is just able to flow therebetween. However, the inventive concept is not limited thereto, and one surface of the substrate WF may be in contact with the upper surface of the polishing pad 11.

Referring to FIGS. 4, 6, and 7, the processing of the substrate using the slurry in S2 may include rotating the polishing pad 11 on the substrate WF and supplying the slurry SL. For example, the rotating of the polishing pad 11 on the substrate WF and the supplying of the slurry SL may proceed simultaneously.

The rotating of the polishing pad 11 on the substrate WF may include rotating the polishing pad 11 about the first rotation axis X1 and rotating the substrate WF about the second rotation axis X2. For example, as the plate 13 rotates, the polishing pad 11 may rotate about the first rotation axis X1 in a direction such as counterclockwise. As the polishing head 20 rotates, the substrate WF may rotate about the second rotation axis X2 in a direction such as counterclockwise. However, the inventive concept is not limited thereto, and the polishing pad 11 and the substrate WF may both rotate clockwise or the polishing pad 11 and the substrate may rotate in opposite directions (e.g., one clockwise and one counterclockwise).

According to one embodiment, the act of rotating of the polishing pad 11 on the substrate WF may further include rotating the conditioning device 40 about the third rotation axis X3. The conditioning device 40 may rotate clockwise and/or counterclockwise while being in contact with the polishing pad 11. Accordingly, the condition of the polishing pad 11 may be maintained constant or improved.

The supplying of the slurry SL may include discharging the slurry SL through the supply nozzle 31 to cover a portion of the polishing pad 11 and making the slurry SL flow between the substrate W and the polishing pad 11.

Because the polishing pad 11 rotates at the same time as the slurry SL is supplied, the slurry SL may gradually cover an increasing portion of the upper surface of the polishing pad 11 and may eventually cover the entire upper surface of the polishing pad 11. Additionally, the slurry SL may flow between the polishing pad 11 and the substrate WF. Accordingly, some of the slurry SL may be positioned between one surface of the substrate WF and the upper surface of the polishing pad 11.

The slurry SL may include a first region R1 and a second region R2. The first region R1 of the slurry SL may be a region adjacent to a center (e.g., the first rotation axis X1) of the polishing pad 11. The second region R2 of the slurry SL may be a region adjacent to an edge of the polishing pad 11. For example, the first region R1 of the slurry SL may be a use region in which the slurry SL flows between the upper surface of the polishing pad 11 and a lower surface of the substrate WF, and the slurry SL is used in a chemical mechanical polishing process. The second region R2 of the slurry SL may be a loss region in which slurry SL that is not used in the chemical mechanical polishing process moves outward to the edge of the polishing pad 11. In an initial state of the chemical mechanical process, only the first region R1 of the slurry SL may exist, or the second region R2 of the slurry SL may be very small. Afterwards, when the slurry SL is continuously supplied in a constant amount, the second region R2 of the slurry SL may gradually increase. Accordingly, the amount of the slurry SL that is not used and is lost in the chemical mechanical polishing process may increase when the slurry SL is supplied continually with a constant amount.

A portion of the slurry SL supplied to the polishing pad 11 may be lost without being used in the chemical mechanical polishing process for the substrate WF when the slurry SL is supplied continually with a constant amount. Supplying the slurry SL according to embodiments of the inventive concept may reduce the size of the second region R2 of the slurry SL by adjusting the amount of the slurry SL supplied over time. Therefore, the slurry SL used in the chemical mechanical polishing process may be efficiently supplied (e.g., the chemical mechanical polishing process may use the slurry SL more efficiently compared to a continual constant amount of slurry SL).

Referring again to FIGS. 4 and 5, the removing of the substrate from the substrate processing apparatus in S3 may include moving the head support 21 of the polishing head 20 to separate the substrate WF and the polishing pad 11 (e.g., increase the distance between the substrate WF and the polishing pad 11), and removing the substrate WF from the polishing head body 23 of the polishing head 20.

Moving the head support 21 may result in the head support 21 rising in the third direction D3. Accordingly, the polishing head 20 and the substrate WF may be spaced apart from the polishing pad 11 in the third direction D3 by an amount greater than immediately before moving the head support 21. Thereafter, the vacuum pressure of the polishing head body 23 that was used to fix the substrate WF to the polishing head body 23 may be removed so that the substrate WF may be separated from the polishing head body 23. For example, the removing of the substrate from the substrate processing apparatus in S3 may be performed in substantially an opposite order to the preparing of the substrate ins the substrate processing apparatus in S1, but is not limited thereto.

FIGS. 8A to 8D each provide three graphs that show the flow rate of a slurry, the total amount of slurry provided, and the polishing rate for a CMP process according to embodiments of the inventive concept. Each figure represents a different embodiment. Referring to FIGS. 8A to 8D, the horizontal axis of the graph may indicate an elapsed time of a chemical mechanical polishing process. The vertical axis of upper graph in each figure may represent a flow rate of a slurry, the vertical axis of the middle graph in each figure may represent a total amount of the slurry provided, and the vertical axis of the lower graph may represent a polishing rate, which may be dependent on the slurry flow rate and the total amount of slurry provided. Each graph also includes a reference line REF which may represent values in a comparative example in which the slurry is supplied at a constant flow rate. For example, the reference line REF may be representative of a conventional slurry supply method, but is not limited thereto.

Referring to FIG. 8A, values for the flow rate of a slurry, the total amount of slurry supplied, and the polishing rate in a method of supplying slurry according to a first embodiment of the inventive concept is represented by lines C1. The values represented by lines C1 may vary with time during the method of supplying slurry and a function determining the variation of the values may vary in different time intervals. Each time interval may correspond to a slurry supply activity. For example, the horizontal axis in the graphs is divided into first time intervals TP1 and second time intervals TP2 with each time interval corresponding to either a first supply activity or a second supply activity, respectively. Hereafter, time interval will be used to describe the different portions of the graph with the understanding that a specific time interval has a corresponding supply activity. In the first time intervals TP1, a slurry may be supplied at a flow rate characterized by a first function. In the second time intervals TP2, a slurry may be supplied at a flow rate characterized by a second function. For example, the first function may be a linear function of time with a positive slope (e.g., the flow rate increases linearly with time). The second function may be a linear function of time with a negative slope (e.g., the flow rate decreases linearly with time) or a quadrative function of time with a negative slope. That is, in the first embodiment represented by line C1 in FIG. 8A, the flow rate of the slurry supplied during the first time intervals TP1 may increase and the flow rate of the slurry supplied during the second time intervals TP2 may decrease. The first embodiment represented by line C1 in FIG. 8A may have an average flow rate of the slurry that is less than the average flow rate for the comparative example shown by the reference line REF. Accordingly, the first embodiment represented by line C1 in FIG. 8A may have a smaller amount of the slurry supplied than the amount of slurry supplied according to the comparative example shown by the reference line REF. For example, the total amount of the slurry used with the first embodiment represented by line C1 in FIG. 8A may be about 60% to about 80% of the total amount of the slurry used according to the comparative example shown by the reference line REF.

However, the inventive concept is not limited thereto. Each of the first function and the second function may be a quadratic or higher function of time, and may be an exponential function, a trigonometric function, or a logarithmic function of time. That is, the first function and the second function may be functions whose values change with time.

The first time intervals TP1 and the second time intervals TP2 according to the first embodiment represented by line C1 in FIG. 8A may alternately and repeatedly proceed. For example, one of the second time intervals TP2 may occur between two consecutive first time intervals TP1, and one of the first time intervals TP1 may occur between two consecutive second time intervals TP2. A flow rate of the slurry may be the same at a point where the first time intervals TP1 and the second time intervals TP2 meet each other (e.g., when the first time intervals TP1 transition to the second time intervals TP2). Accordingly, the first embodiment represented by line C1 in FIG. 8A may have a continuous slurry flow rate (e.g., the slurry may flow continuously). Additionally, a horizontal axis length of each of the first time intervals TP1 may be equal to a horizontal axis length of each of the second time intervals TP2 (e.g., the duration of each of the first time intervals TP1 may be substantially the same as the duration of each of the second time intervals TP2).

As the first embodiment represented by line C1 in FIG. 8A and the comparative example shown by the reference line REF have different slurry flow rates, different polishing rates may be provided. In the first two of the first time intervals TP1, the first embodiment represented by line C1 in FIG. 8A may result in a polishing rate lower than the polishing rate of comparative example shown by the reference line REF. In the first of the second time intervals TP2, the first embodiment represented by line C1 in FIG. 8A may result in a polishing rate higher than the polishing rate of the comparative example shown by reference line REF. In subsequent time intervals, the polishing rate according to the first embodiment represented by line C1 in FIG. 8A may be substantially the same as the comparative example represented by reference line REF. As a result, in the initial three intervals (e.g., the first two of the first time intervals TP1 and the first one of the second time intervals TP2), although the polishing rates of the first embodiment represented by line C1 in FIG. 8A and the comparative example shown by the reference line REF are different from each other, the integral value of the polishing rate may be substantially the same. As the integral value of the polishing rate represents the total polishing amount, the total polishing amount of the first embodiment represented by line C1 in FIG. 8A may be substantially equal to the total polishing amount of the reference line REF. That is, the first embodiment represented by line C1 in FIG. 8A may have substantially the same total polishing amount using a smaller amount of the slurry than comparative example shown by the reference line REF.

Referring to FIG. 8B, the second embodiment represented by line C2 in FIG. 8B of the graph may be a method of supplying a slurry according to an embodiment of the inventive concept. The second embodiment represented by line C2 in FIG. 8B may include first time interval TP1 and second time intervals TP2. In the first time interval TP1, a slurry may be supplied at a flow rate according to a first function, which may be a constant function. In the second time intervals TP2, a slurry may be supplied at a flow rate characterized by a second function. For example, the first function may not change over time and may have a constant value. The second function may be a time-dependent trigonometric function. That is, in the second embodiment represented by line C2 in FIG. 8B, the flow rate of the slurry supplied during the first time interval TP1 may be constant, and the flow rate of the slurry supplied during the second time intervals TP2 may be variously changed with time. The second embodiment represented by line C2 in FIG. 8B may have an average flow rate of the slurry that is less than the comparative example shown by reference line REF. Accordingly, in the second embodiment represented by line C2 in FIG. 8B, the amount of the slurry supplied may be smaller than the amount of slurry supplied in the comparative example shown by reference line REF. For example, the total amount of the slurry in the second embodiment represented by line C2 in FIG. 8B may be about 60% to about 80% of the total amount of the slurry in the comparative example shown by reference line REF.

However, the inventive concept is not limited thereto. The second function may be a linear or higher function over time, and may be an exponential function, or a logarithmic function over time. That is, the first function may be a constant function, and the second function may be a function that changes with time.

The first time interval TP1 may occur once and the second time intervals TP2 of the second embodiment represented by line C2 in FIG. 8B may be performed repeatedly. For example, the second time intervals TP2 may occur continuously after a single first time interval TP1. A flow rate of the slurry at a time when the first time interval TP1 and the second time interval TP2 meet each other may be the same. Accordingly, the second embodiment represented by line C2 in FIG. 8B may have a continuous slurry flow rate. A horizontal axis length of the first time interval TP1 may be different from a horizontal axis length of each of the second time intervals TP2. For example, a duration of the first time interval TP1 may be longer than a duration of each of the second time intervals TP2.

As the second embodiment represented by line C2 in FIG. 8B and the comparative example shown by the reference line REF have different slurry flow rates, different polishing rates may be provided. In the first time interval TP1, the second embodiment represented by line C2 in FIG. 8B may have a polishing rate higher than the polishing rate of the comparative example shown by reference line REF. In the first three of the second time intervals TP2, the second embodiment represented by line C2 in FIG. 8B may have a polishing rate higher than the comparative example shown by reference line REF. A polishing rate in a subsequent second time interval in the second embodiment represented by line C2 in FIG. 8B may have substantially the same polishing rate as the comparative example shown by reference line REF. As a result, in the initial four time intervals (e.g., the first time interval TP1 and the first three of the second time intervals TP2), the second embodiment represented by line C2 in FIG. 8B may have a polishing rate higher than the comparative example shown by reference line REF. As the integral value of the polishing rate represents the total polishing amount, the total polishing amount of the second embodiment represented by line C2 in FIG. 8B may be greater than the total polishing amount of the comparative example shown by reference line REF. That is, the second embodiment represented by line C2 in FIG. 8B may have a substantially larger total polishing amount using a smaller amount of the slurry than the comparative example shown by reference line REF.

Referring to FIG. 8C, a third embodiment represented by line C3 in FIG. 8C of the graph may be a method of supplying slurry according to an embodiment of the inventive concept. The third embodiment represented by line C3 in FIG. 8C may include a first time interval TP1 and a second time intervals TP2. In the first time interval TP1, a slurry may be supplied at a flow rate having a first function, which may be constant for the first time interval. In the second time intervals TP2, a slurry may be supplied at a flow rate characterized by a second function, which may be constant for a single second time interval, but change in subsequent second time intervals (e.g., the second function may be a step function with steps according to the time intervals). For example, each of the first function and the second function may have a constant value for a given time interval without changing over time during the time interval. That is, in the third embodiment represented by line C3 in FIG. 8C, the flow rate of the slurry supplied in each of the first time interval TP1 and the second time intervals TP2 may be constant. The third embodiment represented by line C3 in FIG. 8C may have an average flow rate of the slurry that is less than the reference line REF. Accordingly, in the third embodiment represented by line C3 in FIG. 8C, the amount of the slurry supplied may be smaller than the reference line REF. For example, the total amount of the slurry in the embodiment represented by line C3 in FIG. 8C may be about 60% to about 80% of the total amount of the slurry in the reference line REF.

The second time intervals TP2 of the third embodiment represented by line C3 in FIG. 8C may be repeatedly performed after the first time interval TP1. A flow rate of the slurry in the first time interval TP1 may be greater than a flow rate of the slurry in the second time intervals TP2. Additionally, different slurry flow rates may be provided in the second time intervals TP2. For example, the second time intervals TP2 may include a (2-1)th time interval TP2-1, a (2-2)th time interval TP2-2, a (2-3)th time interval TP2-3, and a (2-4)th time interval TP2-4. A flow rate of the slurry in the (2-1)th time interval TP2-1 may be greater than a flow rate of the slurry in the (2-2)th time interval TP2-2. The flow rate of the slurry in the (2-2)th time interval TP2-2 may be greater than a flow rate of the slurry in the (2-3)th time interval TP2-3. The flow rate of the slurry in the (2-3)th time interval TP2-3 may be greater than a flow rate of the slurry in the (2-4)th time interval TP2-4. The slurry flow rate may be the highest in the (2-1)th time interval TP2-1 and the slurry flow rate may be the lowest in the (2-4)th time interval TP2-4. That is, as the second time intervals TP2 are repeated, the flow rate of the slurry may decrease. The flow rate of the slurry may change at a point when the first time interval TP1 and the second time intervals TP2 meet each other. Accordingly, the third embodiment represented by line C3 in FIG. 8C may have a discontinuous slurry flow rate. Additionally, a length of the horizontal axis of the first time interval TP1 may be different from a length of the horizontal axis of each of the second time intervals TP2. For example, a time of the first time interval TP1 may be longer than a time of each of the second time intervals TP2.

The third embodiment represented by line C3 in FIG. 8C and the comparative example shown by the reference line REF may have different slurry flow rates but substantially the same polishing rate. Accordingly, the third embodiment represented by line C3 in FIG. 8C and the comparative example shown by the reference line REF may have substantially the same integral value of the polishing rate. As the integral value of the polishing rate represents the total polishing amount, the total polishing amount of the third embodiment represented by line C3 in FIG. 8C may be substantially equal to the total polishing amount of the reference line REF. That is, the third embodiment represented by line C3 in FIG. 8C may have substantially the same total polishing amount by using a smaller amount of the slurry than the reference line REF.

Referring to FIG. 8D, a fourth embodiment represented by line C4 in FIG. 8D of the graph may be a method of supplying slurry according to an embodiment of the inventive concept. The fourth embodiment represented by line C4 in FIG. 8D may include the first time interval TP1 and the second time intervals TP2. In the first time interval TP1, a slurry may be supplied at a flow rate characterized by a first function. In the second time intervals TP2, a slurry may be supplied at a flow rate characterized by a second function. For example, each of the first function and the second functions may have a constant value without changing over time (e.g., the function may be a constant function). That is, in the fourth embodiment represented by line C4 in FIG. 8D, the flow rate of the slurry supplied in the first time interval TP1 and the second time interval TP2 may be constant during the time interval, although the flow rate may change between time intervals. The fourth embodiment represented by line C4 in FIG. 8D may have an average flow rate of the slurry that is less than the reference line REF. Accordingly, in the fourth embodiment represented by line C4 in FIG. 8D, the amount of the slurry supplied may be smaller than the reference line REF. For example, the total amount of the slurry in the fourth embodiment represented by line C4 in FIG. 8D may be about 60% to about 80% of the total amount of the slurry in the reference line REF.

The second time intervals TP2 of the fourth embodiment represented by line C4 in FIG. 8D may be repeatedly performed after the first time interval TP1. Additionally, the first time interval TP1 and the second time intervals TP2 may be spaced apart in time. That is, there may be a time interval between the first time interval TP1 and the second time intervals TP2 where slurry is not supplied. Accordingly, the fourth embodiment represented by line C4 in FIG. 8D may have a discontinuous slurry flow rate. A horizontal axis length of the first time interval TP1 may be the same as a horizontal axis length of each of the second time intervals TP2, but is not limited thereto.

As the fourth embodiment represented by line C4 in FIG. 8D and the comparative example shown by the reference line REF have different slurry flow rates, different polishing rates may be provided. In the first time interval TP1, the fourth embodiment represented by line C4 in FIG. 8D may have a polishing rate higher than the reference line REF. In the first of the second time intervals TP2, the fourth embodiment represented by line C4 in FIG. 8D may have a polishing rate higher than the comparative example shown by the reference line REF. In the second of the second time intervals TP2, the fourth embodiment represented by line C4 in FIG. 8D may have a polishing rate lower than the comparative example shown by the reference line REF. As a result, although the polishing rates of the fourth embodiment represented by line C4 in FIG. 8D and the comparative example shown by the reference line REF are different from each other, the integral values of the polishing rates may be substantially the same. As the integral value of the polishing rate represents the total polishing amount, the total polishing amount of the fourth embodiment represented by line C4 in FIG. 8D may be substantially equal to the total polishing amount of the reference line REF. That is, the fourth embodiment represented by line C4 in FIG. 8D may have substantially the same total polishing amount by using a smaller amount of the slurry than the reference line REF.

Referring to FIGS. 9 and 10, the supplying of the slurry in S23 may include a first time interval for supplying the slurry at a flow rate characterized by a first function in S231, a second time interval for supplying the slurry at a flow rate characterized by a second function in S233, a third time interval for supplying the slurry at a flow rate characterized by a third function in S236, a fourth time interval for supplying the slurry at a flow rate characterized by a fourth function in S237, and a fifth time interval for supplying the slurry at a flow rate characterized by a fifth function in S238. For example, the supplying of the slurry in S23 may include a first time interval for supplying the slurry at a flow rate characterized by a first function in S231 to n-th time intervals for supplying the slurry at flow rates characterized by n-th functions, where ‘n’ is 2 or more.

In FIG. 10, the horizontal axis of the graph may indicate a time of the chemical mechanical polishing process. The vertical axis of the upper graph may represent a flow rate of the slurry, the vertical axis of the middle graph may represent a total amount of the slurry provided, and the vertical axis of the lower graph may represent a resulting polishing rate. A comparative example is shown by reference line REF in the graph. The comparative example shown by the reference line REF of the graph may be substantially the same as that described with reference to FIGS. 8A to 8D.

Values represented by line C5 of the graph may correspond to a method of supplying slurry according to a fifth embodiment of the inventive concept. The fifth embodiment represented by line C5 may include the first to fifth time intervals TP1, TP2, TP3, TP4, and TP5. In the first time interval TP1, a slurry may be supplied at a flow rate characterized by a first function. In the second time interval TP2, a slurry may be supplied at a flow rate characterized by a second function. In the third time interval TP3, a slurry may be supplied at a flow rate characterized by a third function. In the fourth time interval TP4, a slurry may be supplied at a flow rate characterized by a fourth function. In the fifth time interval TP5, a slurry may be supplied at a flow rate characterized by a fifth function. The first to fifth functions may be different from each other. For example, the first function may be a constant function that does not change over time. The second function may be a linear function of time with a negative slope. The third function may be a quadratic function of time. The fourth function may be a time-dependent trigonometric function. The fifth function may be a logarithmic function of time. The fifth embodiment represented by line C5 may have an average flow rate of the slurry that is less than the comparative example shown by reference line REF. Accordingly, in the fifth embodiment represented by line C5, the amount of the slurry supplied may be smaller than the comparative example shown by reference line REF. For example, the total amount of the slurry in the fifth embodiment represented by line C5 may be about 60% to about 80% of the total amount of the slurry in the comparative example shown by reference line REF.

The first to fifth time intervals TP1, TP2, TP3, TP4, and TP5 of the fifth embodiment represented by line C5 may be performed in order. For example, the second time interval TP2 may be disposed between the first time interval TP1 and the third time interval TP3, and the fourth time interval TP4 may be disposed between the third time interval TP3 and the fifth time interval TP5. A flow rate of the slurry may be the same at a point when the first to fifth time intervals TP1, TP2, TP3, TP4, and TP5 meet each other. Accordingly, the fifth embodiment represented by line C5 may have a continuous slurry flow rate. A horizontal axis length of each of the first to fifth time intervals TP1, TP2, TP3, TP4, and TP5 may be different. That is, a duration of each of the first to fifth time intervals TP1, TP2, TP3, TP4, and TP5 may be different.

According to one embodiment, at least two of the first to fifth time intervals TP1, TP2, TP3, TP4, and TP5 may be spaced apart from each other. Additionally, at least two times among the first to fifth time intervals TP1, TP2, TP3, TP4, and TP5 may be the same.

As the fifth embodiment represented by line C5 and the comparative example shown by the reference line REF have different slurry flow rates, different polishing rates may be provided. In the first time interval TP1 and the second time interval TP2, the fifth embodiment represented by line C5 may have a polishing rate higher than polishing rate of the comparative example shown by the reference line REF. In the third time interval TP3, the fifth embodiment represented by line C5 may have a polishing rate lower than polishing rate of the comparative example shown by the reference line REF. In the fourth time interval TP4 and the fifth time interval TP5, the fifth embodiment represented by line C5 may have a polishing rate that is substantially the same as or lower than the polishing rate of the comparative example shown by reference line REF. As a result, in the initial three time intervals (e.g., the first to third time intervals TP1, TP2, and TP3), although the polishing rates of the fifth embodiment represented by line C5 are different from each other, the integral value of the polishing rate may be substantially the same. As an integral value of the polishing rate represents the total polishing amount, the total polishing amount of the fifth embodiment represented by line C5 may be substantially equal to the total polishing amount of the comparative example shown by reference line REF. That is, the fifth embodiment represented by line C5 may have substantially the same total polishing amount using a smaller amount of the slurry than the comparative example shown by reference line REF.

According to one embodiment, the supplying of the slurry in S23 may further include repeatedly performing at least one of the first to fifth time intervals TP1, TP2, TP3, TP4, and TP5 as at least one of the first time intervals and the second time intervals described with reference to FIGS. 8A to 8D is repeatedly performed in.

Referring again to FIGS. 8A to 8D and 10, the slurry supplied during a first time interval TP1 may have a flow rate characterized by a first function, and the slurry supplied during a second time interval TP2 may have a flow rate characterized by a second function. For example, the first function and the second function may be different from each other. Additionally, each of the first function and the second function may be a function that changes with time.

According to one embodiment, the slurry may be repeatedly supplied during at least one of the first time interval TP1 and the second time interval TP2. In this case, the first time interval TP1 and the second time interval TP2 may alternately and repeatedly proceed with each other. Alternatively, the second time interval TP2 may repeatedly proceed after the first time interval TP1.

According to one embodiment, the slurry may be further supplied during a third time interval TP3 at a flow rate characterized by a third function after the first time interval TP1 and the second time interval TP2. In this case, the first time interval TP1, the second time interval TP2, and the third time interval TP3 may proceed in order, and the third function may be different from the first function and the second function.

Accordingly, a large amount of the slurry may be supplied at the initial stage of the chemical mechanical polishing process and a relatively small amount of the slurry may be supplied afterwards. The total amount of the slurry used in the chemical mechanical polishing process may be reduced by efficiently supplying the slurry.

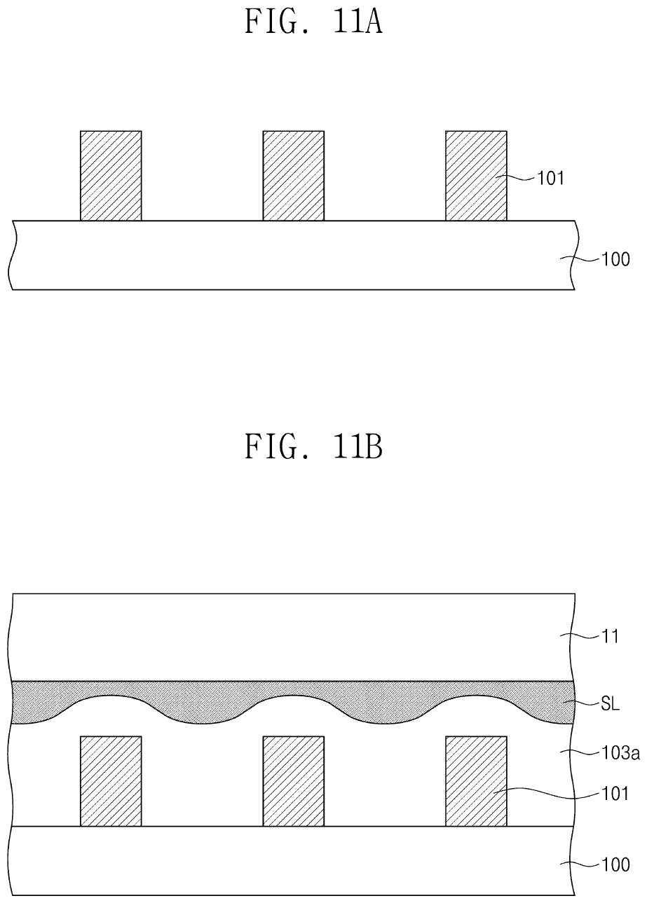

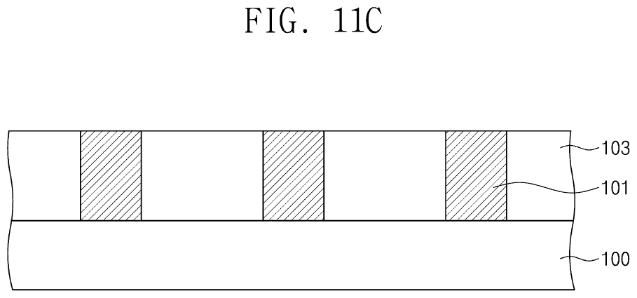

FIGS. 11A to 11C are cross-sectional views illustrating a method of manufacturing a semiconductor device according to embodiments of the inventive concept.

Referring to FIG. 11A, a substrate 100 may be provided. The substrate 100 may be a semiconductor substrate containing silicon (Si), germanium (Ge), silicon-germanium (SiGe), or a compound semiconductor substrate. For example, the substrate 100 may be a silicon (Si) substrate.

First patterns 101 may be formed on the substrate 100. Forming the first patterns 101 may include forming a pattern layer on the substrate 100, forming a mask pattern on the pattern layer, and etching the pattern layer using the mask pattern. The first patterns 101 may be horizontally spaced apart from each other. For example, the first patterns 101 may include, but are not limited to, a semiconductor material, a conductive material, and/or an insulating material.

Referring to FIG. 11B, a layer 103a may be formed on the substrate 100 to cover the substrate 100 and the first patterns 101. The layer 103a may be formed through a deposition process. For example, the deposition process may include a chemical vapor deposition (CVD) and atomic layer deposition (ALD) process. The layer 103a may have an upper surface of different levels between the first patterns 101 and on the first patterns 101. That is, the layer 103a may have an upper surface that is not flat. For example, the layer 103a may include an insulating material such as silicon oxide, silicon nitride, and/or silicon oxynitride, or a semiconductor material such as silicon and/or polysilicon.

Afterwards, a planarization process may be performed to flatten the upper surface of the layer 103a. The planarization process may use a slurry SL. The planarization process may include supplying the slurry SL on one surface of the substrate 100 and rotating a polishing pad 11 on the substrate 100. The slurry SL may be variably supplied on one surface of the substrate 100. For example, the slurry SL may be supplied substantially the same as supplying the slurry in S23 in FIGS. 4 and 9. That is, as described with reference to FIGS. 8A to 8D and FIG. 10, the supplying of the slurry in S23 may include supplying a slurry at a flow rate characterized by a first function in S231 and supplying a slurry at a flow rate characterized by a second function in S233, and the first function and the second function may be different from each other.

Referring to FIG. 11C, a portion of the layer 103a may be removed due to the planarization process, and second patterns 103 may be formed from the layer 103a. The second patterns 103 may have flat upper surfaces. Due to the planarization process, upper surfaces of the first patterns 101 may be exposed. For example, the upper surfaces of the second patterns 103 may be coplanar with the upper surfaces of the first patterns 101.

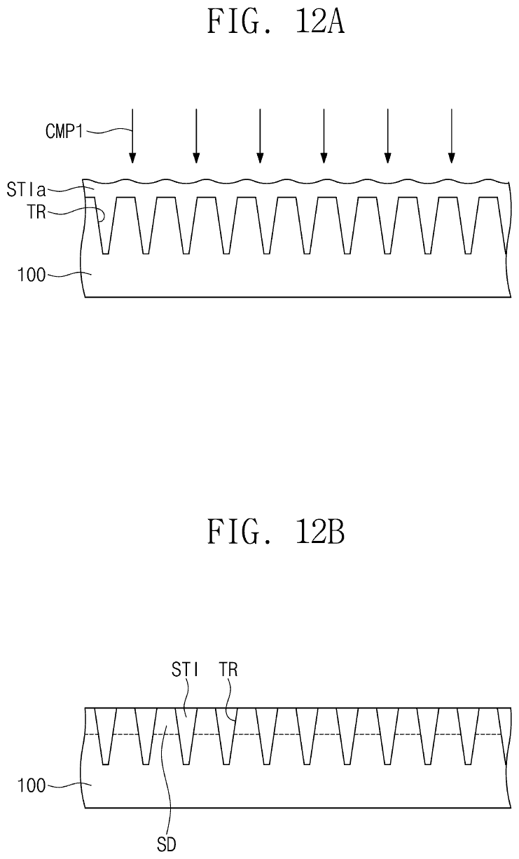

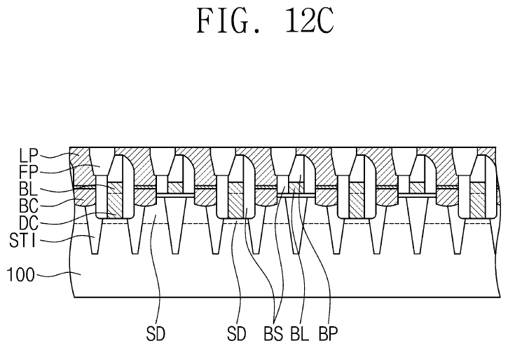

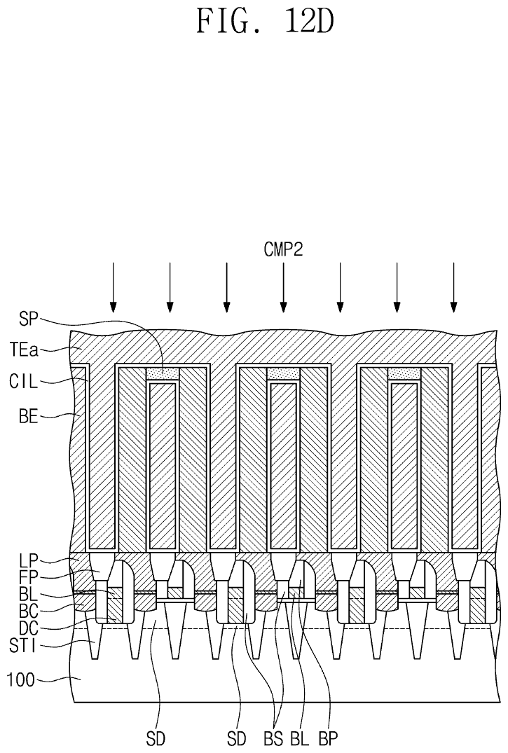

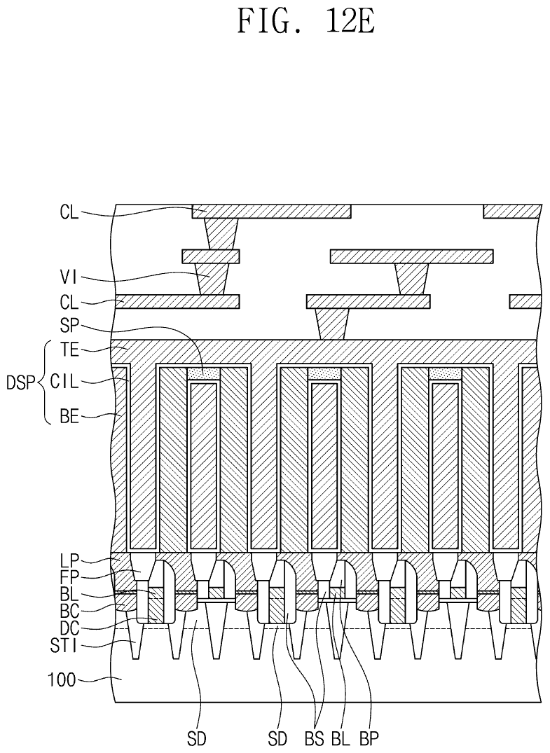

FIGS. 12A to 12E are cross-sectional views illustrating a method of manufacturing a semiconductor device according to embodiments of the inventive concept.

Referring to FIG. 12A, trenches TR may be formed to penetrate a portion of the substrate 100. Forming the trenches TR may include forming a mask pattern on an upper surface of the substrate 100 and etching a portion of the substrate 100 using the mask pattern.

A device isolation layer STIa may be formed to cover the upper surface of the substrate 100 and fill the trenches TR. The device isolation layer STIa may be formed through a deposition process. For example, the deposition process may include a chemical vapor deposition (CVD) or atomic layer deposition (ALD) process with good step coverage. Due to the trenches TR, the device isolation layer STIa may have an uneven upper surface. For example, the device isolation layer STIa may include silicon oxide, silicon nitride, and/or silicon oxynitride.

Afterwards, a first planarization process CMP1 may be performed on the device isolation layer STIa. The first planarization process CMP1 may be substantially the same as the planarization process described with reference to FIGS. 11A to 11C. For example, the first planarization process CMP1 may include supplying a slurry and rotating the polishing pad on the substrate 100, and the supplying of the slurry may include a first time interval of supplying the slurry at a flow rate characterized by a first function, and a second time interval of supplying the slurry at a flow rate characterized by a second function, and the first function and the second function may be different from each other.

Referring to FIG. 12B, a portion of the device isolation layer STIa may be removed through the first planarization process CMP1 to form device isolation patterns STI from the device isolation layer STIa. The device isolation patterns STI may be disposed in the corresponding trenches TR, respectively.

Thereafter, source/drain patterns SD may be formed. The source/drain patterns SD may be regions in the substrate 100 doped with impurities. The source/drain patterns SD may be formed through an ion implantation process, but are not limited thereto. The source/drain patterns SD may be disposed between device isolation patterns STI.

Referring to FIG. 12C, bit line contacts DC, bit lines BL, and bit line capping patterns BP may be formed on some of the source/drain patterns SD. The bit lines BL may be electrically connected to some of the source/drain patterns SD. Thereafter, bit line spacers BS may be formed to cover both sides of the bit line contacts DC, bit lines BL, and bit line capping patterns BP.

Thereafter, storage node contacts BC and landing pads LP may be formed on the remaining of the source/drain patterns SD. The storage node contacts BC may be electrically connected to source/drain patterns SD that are not electrically connected to the bit lines BL. The landing pads LP may be disposed on the storage node contacts BC. The landing pads LP may be electrically connected to the remaining of the source/drain patterns SD through the storage node contacts BC. Filling patterns FP may be formed between the landing pads LP. The charging patterns FP may surround the sides of the landing pads LP.

Referring to FIG. 12D, lower electrodes BE may be formed on each of the landing pads LP. The lower electrodes BE may have a shape extending in a vertical direction. The lower electrodes BE may be horizontally spaced apart from each other. Support patterns SP may be provided on upper surfaces of the lower electrodes BE, but are not limited thereto.

A capacitor dielectric layer CIL may be formed on the lower electrodes BE. The capacitor dielectric layer CIL may cover the lower electrodes BE with a uniform thickness. The capacitor dielectric layer CIL may be formed through a deposition process with excellent step coating properties.

An upper conductive layer TEa may be formed on the capacitor dielectric layer CIL. The upper conductive layer TEa may cover the capacitor dielectric layer CIL and fill the space between the lower electrodes BE. Due to the lower electrodes BE extending in the vertical direction, the upper conductive layer TEa may have an uneven upper surface.

Afterwards, a second planarization process CMP2 may be performed on the upper conductive layer TEa. The second planarization process CMP2 may be substantially the same as the planarization process described with reference to FIGS. 11A to 11C, but is not limited thereto. For example, at least one of the first planarization process CMP1 and the second planarization process CMP2 of FIG. 12A may be substantially the same as the planarization process described with reference to FIGS. 11A to 11C.

Referring to FIG. 12E, a portion of the upper conductive layer TEa may be removed due to the second planarization process CMP2, and the upper electrode TE may be formed from the upper conductive layer Tea. As a result, a data storage pattern DSP including the lower electrodes BE, the capacitor dielectric layer CIL, and the upper electrode TE may be formed. The upper electrode TE may have a flat upper surface due to the second planarization process CMP2. The lower electrodes BE, the capacitor dielectric layer CIL, and the upper electrode TE may form a capacitor. In this case, the semiconductor device may include dynamic random access memory (DRAM).

Conductive lines CL and vias VI connecting adjacent conductive lines CL may be formed on the upper electrode TE. For example, the conductive lines CL and vias VI connected to each other may be formed as a single object body. In this case, forming the conductive lines CL and vias VI may include a planarization process, and the planarization process may be substantially the same as the first planarization process CMP1 of FIG. 12A and/or the second planarization process CMP2 of FIG. 12D.

In the method of processing the substrate and the method of manufacturing the semiconductor device according to embodiments of the inventive concept, the slurry may be variably supplied. In the method of processing the substrate and the method of manufacturing the semiconductor device according to embodiments of the inventive concept, at least one of the first time interval in which the slurry is supplied at the flow rate characterized by the first function and the second time interval in which the slurry is supplied at the flow rate characterized by the second function different from the first function may be repeatedly performed. Accordingly, the amount of the slurry lost during the substrate processing process may be reduced. Therefore, the slurry may be efficiently supplied in the method of processing the substrate and the method of manufacturing the semiconductor device.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A method of manufacturing a semiconductor device, the method comprising:
preparing a substrate in a substrate processing apparatus;
rotating a polishing pad on the substrate; and
supplying a slurry on the polishing pad,
wherein the supplying of the slurry includes:
supplying the slurry during a first time interval at a flow rate characterized by a first function; and
supplying the slurry during a second time interval at a flow rate characterized by a second function,
wherein each of the first function and the second function is a function of time, and
wherein the first function is different from the second function.

2. The method of claim 1, wherein the supplying of the slurry further includes repeatedly performing at least one of supplying the slurry at the flow rate characterized by the first function and supplying the slurry at the flow rate characterized by the second function.

3. The method of claim 2, wherein the repeatedly performing at least one of the supplying the slurry at the flow rate characterized by the first function and supplying the slurry at the flow rate characterized by the second function includes alternately repeatedly performing the supplying the slurry at the flow rate characterized by the first function and supplying the slurry at the flow rate characterized by the second function.

4. The method of claim 2, wherein the repeatedly performing of at least one of the supplying the slurry at the flow rate characterized by the first function and supplying the slurry at the flow rate characterized by the second function includes repeatedly supplying the slurry at the flow rate characterized by the second function and after supplying the slurry at the flow rate characterized by the first function.

5. The method of claim 4, wherein the flow rate characterized by the second function decreases as the supplying the slurry at the flow rate characterized by the second function is repeated.

6. The method of claim 1, wherein the first time interval and the second time interval are spaced apart in time.

7. The method of claim 1, wherein the supplying the slurry further includes a supplying the slurry during a third time interval at a flow rate characterized by a third function, and
wherein the first function, the second function, and the third function are different from each other.

8. The method of claim 7, wherein supplying the slurry during the first time interval, supplying the slurry during the second time interval, and supplying the slurry during the third time interval are performed in order.

9. The method of claim 1, wherein a duration of the first time interval is different from a duration of the second time interval.

10. The method of claim 1, wherein the supplying of the slurry is performed by a slurry supply system,
wherein the slurry supply system includes a supply nozzle that discharges the slurry and a controller connected to the supply nozzle, and
wherein the controller controls the flow rate of the slurry supplied by the supply nozzle.

11. A method of processing a semiconductor device, the method comprising:
forming patterns on a substrate;
forming a layer covering the substrate and the patterns; and
supplying a slurry onto the layer during a planarization process of the layer,
wherein the supplying of the slurry includes:
supplying the slurry during a first time interval a flow rate characterized by a first function;
supplying the slurry during a second time interval at a flow rate characterized by a second function; and
repeatedly performing at least one of supplying the slurry a flow rate characterized by the first function for a first duration and supplying the slurry at a flow rate characterized by the second function for a second duration, and
wherein the first function and the second function are different from each other.

12. The method of claim 11, wherein the first time interval and the second time interval are spaced apart in time, and
wherein the flow rate characterized by the first function is greater than the flow rate characterized by the second function.

13. The method of claim 11, wherein the first function and the second function are functions of time, and
wherein a flow rate of the slurry is continuous between the first time interval and the second time interval.

14. The method of claim 11, wherein the first function and the second function are constant functions, and
wherein a flow rate of the slurry is discontinuous between the first time interval and the second time interval.

15. The method of claim 11, wherein a duration of the first time interval is the same as a time of the second time interval.

16. A method of manufacturing a semiconductor device comprising:
forming a device isolation layer that fills a trench in a substrate;
forming device isolation patterns from the device isolation layer through a first planarization process;
forming bit lines and landing pads electrically connected to source/drain patterns between the device isolation patterns;
forming an upper conductive layer covering a lower electrode and a capacitor dielectric layer formed on the landing pads; and
forming an upper electrode from the upper conductive layer as through a second planarization process,
wherein at least one of the first planarization process and the second planarization process includes supplying a slurry on the substrate during a first time interval and a second time interval, and
wherein the slurry is supplied at different flow rates in each of the first time interval and the second time interval.

17. The method of claim 16, wherein, in the first time interval, the slurry is supplied at a flow rate characterized by a first function,
wherein, in the second time interval, the slurry is supplied at a flow rate characterized by a second function, and
wherein at least one of the first function and the second function is a function of time.

18. The method of claim 17, wherein at least one of supplying the slurry at a flow rate characterized by the first function and supplying the slurry at a flow rate characterized by the second function is repeatedly performed.

19. The method of claim 16, wherein at least one of the first planarization process and the second planarization process further includes supplying the slurry in a third time interval on the substrate, and
wherein a flow rate of the slurry supplied in the third time interval is different from that of the first time interval and the second time interval.

20. The method of claim 16, wherein the lower electrode, the capacitor dielectric layer, and the upper electrode constitute a capacitor.
